(19) United States
(12) Patent Application Publication
(10) Pub. No.: US 2026/0090389 A1
(43) Pub. Date: Mar. 26, 2026

(54) SEMICONDUCTOR PACKAGE AND MANUFACTURING METHOD FOR SAME

(71) Applicant: SAMSUNG ELECTRONICS CO., LTD., Suwon-si (KR)

(72) Inventor: Hyunsoo CHUNG, Suwon-si (KR)

(73) Assignee: SAMSUNG ELECTRONICS CO., LTD., Suwon-si (KR)

(21) Appl. No.: 19/169,748

(22) Filed: Apr. 3, 2025

(30) Foreign Application Priority Data
Sep. 25, 2024 (KR) 10-2024-0129856

(51) Int. Cl. H01L 23/552; H01L 21/56; H01L 23/00; H01L 23/31; H01L 23/48; H01L 25/00; H01L 25/18

(52) U.S. Cl. CPC H10W 42/20; H10W 20/20; H10W 74/01; H10W 74/121; H10W 90/00; H10W 72/926; H10W 72/967; H10W 90/792

(57) ABSTRACT

An embodiment of the disclosure provides a semiconductor package, including a first semiconductor chip including a semiconductor substrate and a through via penetrating the semiconductor substrate, a chip structure on the first semiconductor chip and including at least one second semiconductor chip, a first shielding film covering a side surface of the chip structure, extending over the first semiconductor chip, and electrically connected to the through via, a molding material covering the first shielding film on the first semiconductor chip, and a second shielding film extending over the chip structure and the molding material and connected to the first shielding film.

### CROSS-REFERENCE TO RELATED APPLICATION

This application claims priority to and the benefit of Korean Patent Application No. 10-2024-0129856, filed on Sep. 25, 2024, in the Korean Intellectual Property Office, the disclosure of which is herein incorporated by reference in its entirety.

### BACKGROUND

### 1. Field

One or more example embodiments of the disclosure relate to a semiconductor package and a manufacturing method for the same.

### 2. Description of the Related Art

In the semiconductor industry, a three-dimensional (3D) integrated circuit (IC) package is known for vertically stacking and connecting semiconductor chips to achieve miniaturization, high performance, and high integration of products. For example, 3D ICs may be manufactured using a hybrid bonding technology that directly bonds (e.g., Cu—Cu bonding) the pads of each of upper and lower semiconductor chips. The hybrid bonding technology enables fine pitch implementation, thinning, and high-speed data transmission of products.

### SUMMARY

One or more example embodiments of the disclosure provide a semiconductor package capable of blocking electromagnetic interference (EMI) and a manufacturing method for the same.

One or more example embodiments of the disclosure provide a semiconductor package and a manufacturing method for the same capable of preventing metal migration and electrical short circuit caused therefrom.

An aspect of an example embodiment of the disclosure provides a semiconductor package, including: a first semiconductor chip including a semiconductor substrate and a through via penetrating the semiconductor substrate; a chip structure on the first semiconductor chip and including at least one second semiconductor chip; a first shielding film covering a side surface of the chip structure, extending over the first semiconductor chip, and electrically connected to the through via; a molding material covering the first shielding film on the first semiconductor chip; and a second shielding film extending over the chip structure and the molding material and connected to the first shielding film.

An aspect of an example embodiment of the disclosure provides a semiconductor package, including: a first semiconductor chip having a central region and an edge region surrounding the central region, the first semiconductor chip including a first semiconductor substrate extending in the central region and the edge region, a first through via penetrating the first semiconductor substrate at the edge region, a first pad and a second pad respectively on opposite surfaces of the first semiconductor chip and electrically connected to the first through via, a second through via penetrating the first semiconductor substrate in the central region, and a third pad and a fourth pad respectively on the opposite surfaces of the first semiconductor chip and connected to the second through via; a chip structure on the central region of the first semiconductor chip and including a plurality of stacked second semiconductor chips, each second semiconductor chip including a second semiconductor substrate, a third through via penetrating the second semiconductor substrate, and a fifth pad and a sixth pad respectively on opposite surfaces of each second semiconductor chip and electrically connected to the third through via; a first shielding film covering a side surface of the chip structure, extending over the first semiconductor chip, and electrically connected to the first through via; an insulating layer extending between the chip structure and the first shielding film and between the first semiconductor chip and the first shielding film; a molding material covering the first shielding film on the first semiconductor chip; and a second shielding film extending over the chip structure and the molding material and connected to the first shielding film, wherein the fifth pad of each of the plurality of second semiconductor chips is in contact with the sixth pad of another second semiconductor chip among the plurality of second semiconductor chips or the fourth pad of the first semiconductor chip.

An aspect of an example embodiment of the disclosure provides a manufacturing method for a semiconductor package, including: placing a chip structure including a plurality of semiconductor chips stacked on a wafer, the wafer including a semiconductor substrate and a first through via penetrating the semiconductor substrate; forming an insulating layer covering the wafer and the chip structure; forming a first shielding film covering the insulating layer and electrically connected to the first through via; forming a molding material covering the first shielding film; grinding the molding material, the first shielding film, and the insulating layer to expose the chip structure; forming a second shielding film on the chip structure and the molding material to form a wafer-level semiconductor package; and singulating the wafer-level semiconductor package.

According to an aspect of the disclosure, a semiconductor package capable of blocking electromagnetic interference (EMI) and a manufacturing method for the same may be provided.

According to another aspect of the disclosure, a semiconductor package capable of preventing metal migration and electrical short circuit caused therefrom and a manufacturing method for the same may be provided.

### BRIEF DESCRIPTION OF THE DRAWINGS

Example embodiments will be more clearly understood from the following detailed description taken in conjunction with the accompanying drawings.

FIG. 1 is a cross-sectional view of a semiconductor package according to an embodiment.

FIG. 2 is an enlarged view of a first semiconductor chip of FIG. 1.

FIGS. 3 to 5 are enlarged views of region A of FIG. 1.

FIG. 6 is a cross-sectional view of a semiconductor package according to another embodiment.

FIGS. 7 to 14 are diagrams of a manufacturing process for a semiconductor package according to an embodiment.

### DETAILED DESCRIPTION

The disclosure will be described in detail hereinafter with reference to the accompanying drawings, in which embodiments of the disclosure are shown. As those skilled in the art would understand, the described embodiments may be modified in various different ways, all without departing from the spirit or scope of the disclosure.

The drawings and description should be understood as illustrative in nature and not restrictive, and like reference numerals designate like elements throughout the specification.

Further, sizes and thicknesses of constituent members shown in the accompanying drawings may be arbitrarily given to facilitate understanding and ease of description, and the disclosure is not limited to the illustrated sizes and thicknesses. In the drawings, the thicknesses of layers and regions may be exaggerated for clarity. In the drawings, to facilitate understanding and ease of description, the thicknesses of some layers and regions may be exaggerated.

Throughout the specification, the term “connected” may mean not only “directly connected,” but also “indirectly connected” with another element in between. In a similar perspective, the term “connected” may include being “physically connected,” as well as being “electrically connected.”

It should be understood that when an element such as a layer, film, region, or substrate is referred to as being “on” another element, the element may be directly on the other element or intervening elements may also be present. In contrast, when an element is referred to as being “directly on” another element, there are no intervening elements present. Further, when an element is described as being “on” or “above” a reference element, it may mean the element is on or above or below the reference element, and the element may not necessarily be referred to as being positioned “on” or “above” the reference element in a direction opposite to gravity.

In addition, unless explicitly stated to the contrary, the word “comprise” and variations such as “comprises” or “comprising” should be understood to imply the inclusion of stated elements but not the exclusion of any other elements.

In addition, the phrase “on a plane” may mean a view from a position above the object (e.g., from the top), and the phrase “in a cross-section” may mean a view of a cross-section of the object which is vertically cut from the side.

In addition, throughout the specification, although the terms “first,” “second,” and the like are used to explain various components, the components are not limited to such terms but are only used to distinguish one component from another component. Accordingly, a configuration referred to as the first component in a certain part of the specification may also be referred to as the second component in other parts of the specification.

As used herein, the singular forms are intended to include the plural forms unless the context clearly indicates otherwise.

Additionally, throughout the specification, references to directions such as upper surface, upper side, upper part, lower surface, lower side, and lower part are intended to aid description and understanding with reference to the drawings.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the disclosure to “one embodiment,” “an embodiment,” “an example embodiment,” or similar language may indicate that a particular feature, structure, or characteristic described in connection with the indicated embodiment is included in at least one embodiment of the disclosure. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Hereinafter, a semiconductor package and a manufacturing method for the same according to the disclosure will be described with reference to the drawings.

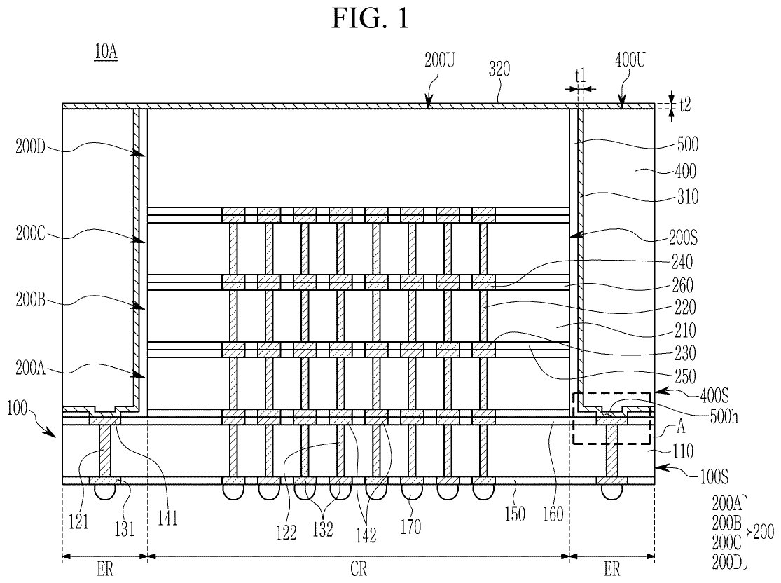

FIG. 1 is a cross-sectional view of a semiconductor package according to an embodiment.

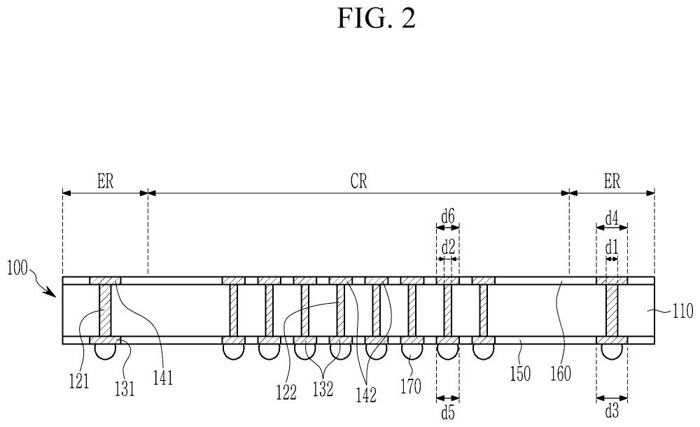

FIG. 2 is an enlarged view of a first semiconductor chip of FIG. 1.

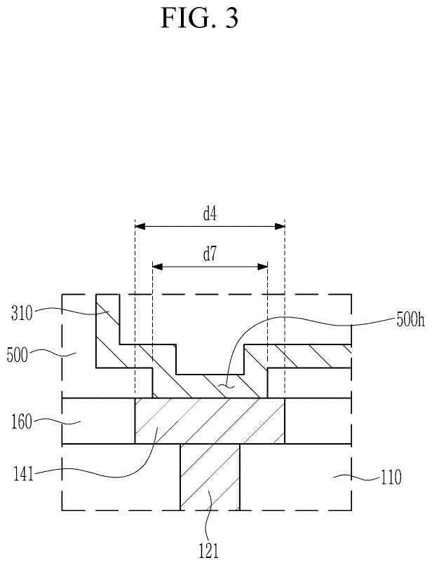

FIGS. 3 to 5 are enlarged views of region A of FIG. 1.

A semiconductor package 10A may include a first semiconductor chip 100, a chip structure 200, a first shielding film 310, a second shielding film 320, a molding material 400, and an insulating layer 500.

The first semiconductor chip 100 has a central region CR and an edge region ER surrounding the central region CR, and may include a first semiconductor substrate 110, through a first via 121 and a second via 122, a first pad 131, a second pad 141, a third pad 132, a fourth pad 142, a first passivation film 150, a second passivation film 160, and conductive bumps 170.

The chip structure 200 may be disposed on the central region CR of the first semiconductor chip 100, and thus the central region CR may overlap the chip structure 200 in a vertical direction. On the other hand, the edge region ER of the first semiconductor chip 100 may be misaligned with the chip structure 200 in the vertical direction. Here, “vertical direction” may mean a direction in which the first semiconductor chip 100 and the chip structure 200 are stacked, that is, a direction from the first semiconductor chip 100 toward the chip structure 200.

The first semiconductor substrate 110 may extend and be disposed in the central region CR and the edge region ER.

A type of semiconductor included in the first semiconductor substrate 110 is not particularly limited, and the first semiconductor substrate 110 may include a semiconductor element such as silicon (Si), germanium (Ge), or a compound semiconductor such as gallium arsenide (GaAs), and indium arsenide (InAs).

The first and second through vias 121 and 122 may penetrate the first semiconductor substrate 110 and may be connected to corresponding ones of the first pad 131, the second pad 141, the third pad 132, and the fourth pad 142.

The first through via 121 may be connected to the first pad 131 and the second pad 141, and the second through via 122 may be connected to the third pad 132 and the fourth pad 142.

The first and second through vias 121 and 122 may be directly connected to the first to fourth pads 131, 141, 132, and 142, or may be indirectly connected to the first to fourth pads 131, 141, 132, and 142. As a non-limiting example, the first through via 121 and the second through via 122 may be connected to the first pad 131 and the third pad 132, respectively, through an internal wiring of the first semiconductor chip 100.

The first through via 121 may be disposed in the edge region ER of the first semiconductor chip 100. Therefore, the first through via 121 may be misaligned in the vertical direction with the chip structure 200 of the first semiconductor chip 100.

The first through via 121 may be connected to the first shielding film 310. The first through via 121 may include a ground via and may ground the first shielding film 310. The first through via 121 functioning as the ground via may be connected to a ground external to the semiconductor package 10A, for example, a ground of a system including the semiconductor package 10A. In an embodiment, the first through via 121 may be connected to a ground wiring among internal wirings of the first semiconductor chip 100.

The first through via 121 may be connected to the first shielding film 310 through the second pad 141. Alternatively, the first through via 121 may be directly connected to the first shielding film 310.

The second through via 122 may be disposed in the central region CR of the first semiconductor chip 100 and may overlap the chip structure 200 in the vertical direction. The second through via 122 may be connected to the chip structure 200 through the fourth pad 142. The second through via 122 may include at least one of a signal via for signal transmission, a power via for power supply, and a ground via for grounding.

The first and second through vias 121 and 122 may include a conductive material such as copper (Cu), tungsten (W), silver (Ag), nickel (Ni), and/or polysilicon. An insulating barrier film may be interposed between outer surfaces of the first and second through vias 121 and 122 and the first semiconductor substrate 110.

The first and second through vias 121 and 122 may be formed using a via first, a via middle, or a via last method. Depending on the method of forming the first and second through vias 121 and 122, a depth and a region of the first semiconductor chip 100 through which the first and second through vias 121 and 122 penetrate may vary.

The first to fourth pads 131, 141, 132, and 142 may include the first pad 131 and the second pad 141 electrically connected to the first through via 121, and the third pad 132 and the fourth pad 142 electrically connected to the second through via 122.

The first pad 131 may be disposed on a lower surface of the first semiconductor chip 100, and the second pad 141 may be disposed on an upper surface of the first semiconductor chip 100. The first pad 131 may be used to connect the first semiconductor chip 100 to a substrate on which the semiconductor package 10A is mounted, and the second pad 141 may connect the first through via 121 to the first shielding film 310.

The lower surface of the first semiconductor chip 100 may be an active surface adjacent to individual elements and an internal wiring of the first semiconductor chip 100. In other words, the individual elements and the internal wiring may be present between the first semiconductor substrate 110 and the lower surface of the first semiconductor chip 100 on which the first pad 131 is disposed. The upper surface of the first semiconductor chip 100 may be an inactive surface, which is a surface opposite to the active surface.

The first pad 131 and the second pad 141 may be disposed on the edge region ER of the first semiconductor chip 100 together with the first through via 121. However, depending on a design, at least a part of the first pad 131 may be disposed in the central region CR of the first semiconductor chip 100 and connected to the first through via 121 through the internal wiring of the first semiconductor chip 100.

The first pad 131 and the second pad 141 may be ground pads and may be connected to the ground of the system including the semiconductor package 10A together with the first through via 121—e.g., the ground external to the semiconductor package 10A.

The third pad 132 may be disposed on the lower surface of the first semiconductor chip 100, and the fourth pad 142 may be disposed on the upper surface of the first semiconductor chip 100. The third pad 132 may be used to connect the first semiconductor chip 100 to the substrate on which the semiconductor package 10A is mounted, and the fourth pad 142 may connect the first semiconductor chip 100 to the chip structure 200. The third pad 132 and the fourth pad 142 may be disposed in the central region CR of the first semiconductor chip 100 together with the second through via 122.

Referring to FIG. 2, a diameter d1 of the first through via 121 may be larger than a diameter d2 of the second through via 122. A diameter d3 of the first pad 131 and a diameter d4 of the second pad 141 may be larger than a diameter d5 of the third pad 132 and a diameter d6 of the fourth pad 142. The first through via 121, the first pad 131, and the second pad 141 may be disposed in the edge region ER of the first semiconductor chip 100 and may be used for grounding, such that their size and position may be freely designed. On the other hand, the second through via 122, the third pad 132, and the fourth pad 142 may perform a function such as signal transmission, and may be designed to have an optimal size to secure electrical performance and be disposed within a limited space.

The diameter d3 of the first pad 131 and the diameter d4 of the second pad 141 may be the same or different. The diameter d5 of the third pad 132 and the diameter d6 of the fourth pad 142 may be the same or different.

The first and second passivation films 150 and 160 may protect the upper and lower surfaces of the first semiconductor chip 100. In addition, the passivation films 150 and 160 may function as a bonding film in a hybrid bonding, which will be described later. The first passivation film 150 may be disposed on the lower surface of the first semiconductor chip 100 to fill spaces between the first pad 131 and the third pad 132 (in other words, embedding the first pad 131 and the third pad 132), and the second passivation film 160 may be disposed on the upper surface of the first semiconductor chip 100 to fill spaces between the second pad 141 and the fourth pad 142 (in other words, embedding the second pad 141 and the fourth pad 142). The first and second passivation films 150 and 160 may not cover upper and lower surfaces of the first to fourth pads 131, 141, 132, and 142, to enable connection of the first to fourth pads 131, 141, 132, and 142.

The conductive bumps 170 may be disposed on the first pad 131 and the third pad 132. The conductive bump 170 may electrically connect the semiconductor package 10A to other components such as the substrate on which the semiconductor package 10A is mounted. A conductive material such as solder may be used as the material for the conductive bumps 170. A number, arrangement, spacing, etc. of the conductive bumps 170 are not particularly limited.

The first semiconductor chip 100 may include a logic chip. The logic chip may include at least one of an application processor (AP), a microprocessor, a central processing unit (CPU), a graphic processing unit (GPU), a neural processing unit (NPU), an application-specific integrated circuit (ASIC), and a system-on-chip (SoC).

The chip structure 200 may be disposed on the central region CR of the first semiconductor chip 100 and may include one or more second semiconductor chips 200A, 200B, 200C, and 200D.

For example, the chip structure 200 may include four, eight, twelve, or sixteen stacked second semiconductor chips.

The second semiconductor chips 200A, 200B, and 200C, may each include a second semiconductor substrate 210, a third through via 220, a fifth pad 230, a sixth pad 240, a third passivation film 250, and a fourth passivation film 260.

However, among the second semiconductor chips 200A, 200B, 200C, and 200D, an uppermost semiconductor chip 200D may not include the third through via 220, the sixth pad 240, or the fourth passivation film 260 for connection with an upper configuration. In other words, the second semiconductor chip 200D may include the second semiconductor substrate 210, the fifth pad 230, and the third passivation film 250.

The type of the semiconductor included in the second semiconductor substrate 210 is not particularly limited, and the second semiconductor substrate 210 may include a semiconductor element such as silicon (Si), germanium (Ge), or a compound semiconductor such as gallium arsenide (GaAs), indium arsenide (InAs), or the like.

The third through via 220 may penetrate the second semiconductor substrate 210 and may be connected to the fifth pad 230 and the sixth pad 240. The third through via 220 may be connected to the fifth and sixth pads 230 and 240 by direct contact, or may be indirectly connected to the fifth and sixth pads 230 and 240. As a non-limiting example, the third through via 220 may be connected to the fifth pad 230 through an internal wiring of a corresponding one of the second semiconductor chips 200A, 200B, 200C, and 200D.

The third through via 220 may include a conductive material such as copper (Cu), tungsten (W), silver (Ag), nickel (Ni), or polysilicon. An insulating barrier film may be interposed between an outer surface of the third through via 220 and the second semiconductor substrate 210.

The third through via 220 may be formed using via first, via middle or via last method. Depending on the method for forming the third through via 220, a depth and a region of the second semiconductor chips 200A, 200B, 200C, and 200D through which the third through via 220 penetrates may vary.

The fifth pad 230 may be disposed on lower surfaces of the second semiconductor chips 200A, 200B, 200C, and 200D, and the sixth pad 240 may be disposed on upper surfaces of the second semiconductor chips 200A, 200B, and 200C. The fifth pad 230 of one of the second semiconductor chips 200A, 200B, 200C, and 200D may be connected to the sixth pad 240 of another of the second semiconductor chips 200A, 200B, and 200C or the fourth pad 142 of the first semiconductor chip 100, and the sixth pad 240 of one of the second semiconductor chips 200A, 200B, and 200C may be connected to the fifth pad 230 of another of the second semiconductor chips 200B, 200C, and 200D.

The third and fourth passivation films 250 and 260 may protect the upper and lower surfaces of the second semiconductor chips 200A, 200B, 200C, and 200D. In addition, the fifth and fourth passivation films 150 and 160 may function as a bonding film in the hybrid bonding described later. The third passivation film 250 may be disposed on the lower surface of each of the second semiconductor chips 200A, 200B, 200C, and 200D to fill spaces between the fifth pads 230 (in other words, embedding the fifth pads 230), and the second passivation film 260 may be disposed on the upper surface of each of the second semiconductor chips 200A, 200B, and 200C to fill spaces between the sixth pads 240 (in other words, embedding the sixth pads 240). However, the passivation films 250 and 260 may not cover the upper and lower surfaces of the fifth and sixth pads 230 and 240 to allow connection of the fifth and sixth pads 230 and 240.

The uppermost semiconductor chip 200D may have a thicker thickness than the other second semiconductor chips 200A, 200B, and 200C for heat dissipation characteristics of the semiconductor package 10A. However, depending on a size required for the semiconductor package 10A, the uppermost semiconductor chip 200D may have a thickness that is the same as or thinner than the other second semiconductor chips 200A, 200B, and 200C.

The second semiconductor chips 200A, 200B, 200C, and 200D may include a memory chip. The memory chip may include at least one of a high-bandwidth memory (HBM) chip, a dynamic random-access memory (DRAM) chip, a static random-access memory (SRAM) chip, a flash memory chip, a read-only memory (ROM) chip, and a magnetic random-access memory (MRAM) chip.

The second semiconductor chips 200A, 200B, 200C, and 200D may include a logic chip.

The types of each of the second semiconductor chips 200A, 200B, 200C, and 200D may be the same or different.

In an embodiment, the second semiconductor chips 200A, 200B, 200C, and 200D may be hybrid-bonded. For example, the fifth pad 230 of each of the second semiconductor chips 200B, 200C, and 200D may be in contact with the sixth pad 240 of another of the second semiconductor chips 200A, 200B, and 200C among the second semiconductor chips 200A, 200B, 200C, and 200D. The third passivation film 250 of each of the second semiconductor chips 200B, 200C, and 200D may be in contact with the sixth passivation film 260 of another of the second semiconductor chips 200A, 200B, and 200C among the second semiconductor chips 200A, 200B, 200C, and 200D. However, the second semiconductor chips 200A, 200B, 200C, and 200D may be bump-bonded using conductive bumps.

In an embodiment, the chip structure 200 and the first semiconductor chip 100 may also be hybrid-bonded. For example, the fifth pad 230 of the lowest semiconductor chip 200A among the second semiconductor chips 200A, 200B, 200C, and 200D may be in contact with the fourth pad 142 of the first semiconductor chip 100. The third passivation film 250 of a lowermost semiconductor chip 200A among the second semiconductor chips 200A, 200B, 200C, and 200D may be in contact with the second passivation film 160 of the first semiconductor chip 100. However, the chip structure 200 and the first semiconductor chip 100 may also be bump-bonded using conductive bumps.

A first shielding film 310 and a second shielding film 320 may cover the chip structure 200 to block electromagnetic interference (EMI) of the chip structure 200, thereby providing signal integrity and improving performance and reliability of a product. In the disclosure, when a component covers another component, it may mean not only that the another component may be directly covered by simply contacting the covering component, but also that there may be a space between the covering component and the covered component, or that a third component may be interposed between the covering component and the covered component.

The first shielding film 310 may cover a side surface 200S of the chip structure 200 to block electromagnetic interference through the side surface 200S of the chip structure 200.

The first shielding film 310 may extend over the first semiconductor chip 100 and be electrically connected to the first through via 121. The first shielding film 310 may be grounded through the first through via 121 to minimize electromagnetic interference.

The first shielding film 310 may extend to a level where an upper surface 200U of the chip structure 200 is located. Accordingly, one end of the first shielding film 310 may be disposed at a level where the upper surface 200U of the chip structure 200 is located. As described below, after the first shielding film 310 is formed to cover the chip structure 200 during the manufacturing process of the semiconductor package 10A, the region of the first shielding film 310 covering the upper surface 200U of the chip structure 200 may be removed during a grinding process for adjusting a thickness of the chip structure 200.

The first shielding film 310 may be exposed on a side surface 400S of the molding material 400 on the first semiconductor chip 100. This is because the first shielding film 310 may be manufactured by singulating a wafer-level semiconductor package manufactured by chip-to-wafer bonding, and the first shielding film 310 disposed at a cutting line during singulation may be cut together with the molding material 400.

A thickness t1 of the first shielding film 310 may be 0.1 μm or greater and 20 μm or less. If the thickness t1 of the first shielding film 310 is less than 0.1 μm, an electromagnetic shielding effect provided by the first shielding film 310 may be minimal, and if the thickness t1 of the first shielding film 310 exceeds 20 μm, a process cost and time for the first shielding film 310 may be excess, and a size and a weight of the semiconductor package 10A may increase. The thickness t1 of the first shielding film 310 may refer to a thickness in a direction from a configuration (or structure) covered by the first shielding film 310 toward the first shielding film 310. For example, the thickness of the first shielding film 310 in a region covering the side surface 200S of the chip structure 200 may refer to the thickness in a direction from the chip structure 200 toward the first shielding film 310. The thickness of the first shielding film 310 in a region covering the first semiconductor chip 100 may refer to the thickness in a direction from the first semiconductor chip 100 toward the first shielding film 310.

The second shielding film 320 may extend over the chip structure 200 and over the molding material 400 and connected to the first shielding film 310, and may block electromagnetic interference through the upper surface 200U of the chip structure 200. For example, the second shielding film 320 may be disposed directly on and in contact with the chip structure 200, the molding material 400, the first shielding film 310, and the insulating layer 500.

The second shielding film 320 may be electrically connected to the first through via 121 through the first shielding film 310 and grounded through the first through via 121 to minimize electromagnetic interference.

The second shielding film 320 may extend to the side surface 400S of the molding material 400. This is because when singulating a semiconductor package at the wafer level, the second shielding film 320 disposed on the cutting line may be cut together with the molding material 400.

A thickness t2 of the second shielding film 320 may be 0.1 μm or greater and 20 μm or less. If the thickness t2 of the second shielding film 320 is less than 0.1 μm, the electromagnetic shielding effect provided by the second shielding film 320 may be minimal, and if the thickness t2 of the second shielding film 320 exceeds 20 μm, a process cost and time for the second shielding film 320 may be excess, and the size and the weight of the semiconductor package 10A may increase. The thickness t2 of the second shielding film 320 may refer to the thickness in a direction from the chip structure 200 (or molding material 400) toward the second shielding film 320.

A conductive material may be used as a material for the first shielding film 310 and the second shielding film 320. For example, copper (Cu), titanium (Ti), stainless steel (SUS), etc. may be used.

The first shielding film 310 and the second shielding film 320 may have a boundary, but may not have a boundary that can be seen with a naked eye depending on their materials, manufacturing methods, etc.

The molding material 400 may cover the first shielding film 310 on the first semiconductor chip 100.

The upper surface 400U of the molding material 400 may be substantially coplanar with the upper surface 200U of the chip structure 200. In the disclosure, “substantially” coplanar may mean including cases in which there is a small level difference due to an error in the process. This is because, during the manufacturing process of the semiconductor package 10A, after forming the molding material 400 that covers the chip structure 200, a region of the molding material 400 that covers the chip structure 200 may be removed in a grinding process that adjusts the thickness of the chip structure 200 to expose the chip structure 200.

The side surface 400S of the molding material 400 may be substantially coplanar with the side surface 100S of the first semiconductor chip 100. This is because when singulating a semiconductor package at the wafer level, the wafer and the molding material 400 for forming the first semiconductor chip 100 may be cut together.

An insulating material such as an epoxy molding compound (EMC) may be used as the material for the molding material 400.

The insulating layer 500 may provide a smooth surface for uniform deposition and prevention of peeling of the first shielding film 310. When the first shielding film 310 is directly formed on the chip structure 200, uniform deposition of the first shielding film 310 may be difficult due to an alignment error, etc., when stacking the second semiconductor chips 200A, 200B, 200C, and 200D.

The insulating layer 500 may prevent moisture from penetrating through an interface of the semiconductor chips 100, 200A, 200B, 200C, and 200D, thereby preventing metal migration of pads and resulting electrical short circuits.

The insulating layer 500 may be disposed between the chip structure 200 and the first shielding film 310, and may extend between the first semiconductor chip 100 and the first shielding film 310.

The insulating layer 500 may extend to a level where the upper surface 200U of the chip structure 200 is located together with the first shielding film 310, and may be exposed to the side surface 400S of the molding material 400 on the first semiconductor chip 100.

The insulating layer 500 may have an opening 500h including a region overlapping the first through via 121. The second pad 141 may be exposed through the opening 500h of the insulating layer 500, and the first shielding film 310 may fill at least a portion of the opening 500h (e.g., extend along a wall surface and a bottom surface of the opening 500h) and be connected to the second pad 141 and the first through via 121.

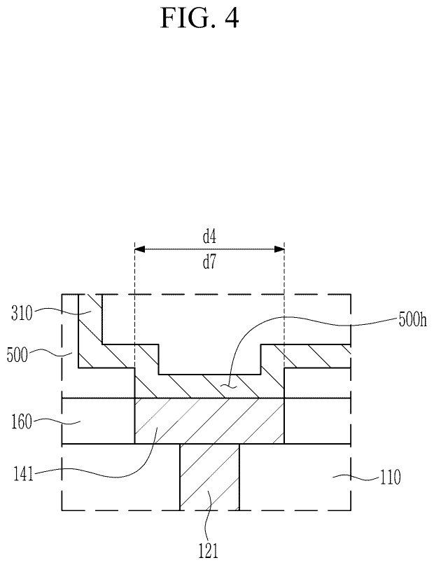

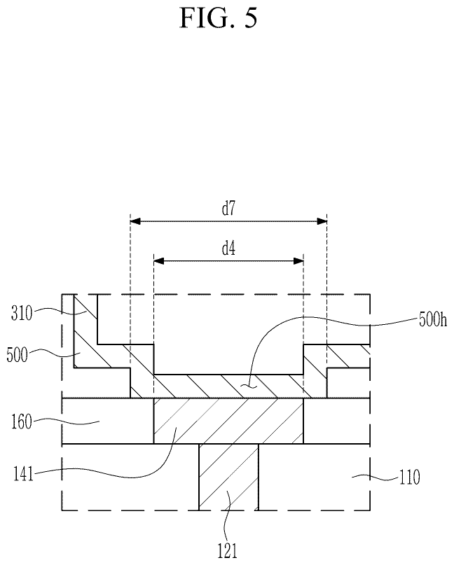

Referring to FIGS. 3 to 5, a diameter d7 of the opening 500h of the insulating layer 500 may be smaller than the diameter d4 of the second pad 141 as shown in FIG. 3, may be equal to the diameter d4 of the second pad 141 as shown in FIG. 4, or may be larger than the diameter d4 of the second pad 141 as shown in FIG. 5. However, for stable connection between the first shielding film 310 and the second pad 141, it may be desirable for the diameter d7 of the opening 500h to be greater than or equal to the diameter d4 of the second pad 141.

The insulating layer 500 may include an insulating material and may include, for example, at least one of silicon oxide and silicon nitride.

Meanwhile, in a three-dimensional (3D) integrated circuit (IC) structure where hybrid-bonding is applied, a frequency used increases as a data transmission speed increases, and thus, a method to minimize electromagnetic interference (EMI) is needed. Additionally, hybrid-bonding is vulnerable to moisture absorption and impact, and moisture penetrating through the interfaces of semiconductor chips may cause metal migration of the pads, resulting in electrical short circuits.

According to the disclosure, it is possible to block electromagnetic interference through the first and second shielding films 310 and 320 covering the chip structure 200, thereby providing signal integrity and improving the performance and reliability of a product. Further, it is possible to provide uniform deposition for the shielding film and prevent peeling by introducing the insulating layer 500 between the chip structure 200 and the shielding film 310. In addition, the insulating layer 500 may prevent moisture from penetrating through the interface of semiconductor chips, thereby preventing metal migration of pads that results in electrical short circuits.

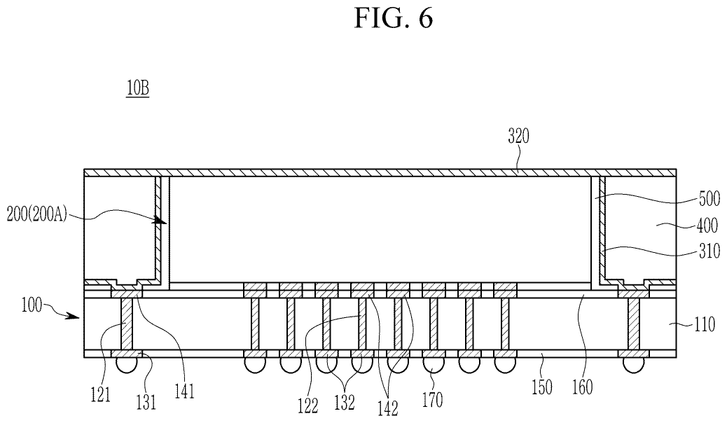

FIG. 6 is a cross-sectional view of a semiconductor package according to another embodiment.

Referring to the drawings, the first and second shielding films 310 and 320 and the insulating layer 500 according to the disclosure may also be applied to a 3D IC semiconductor package 10B including a single semiconductor chip 200A.

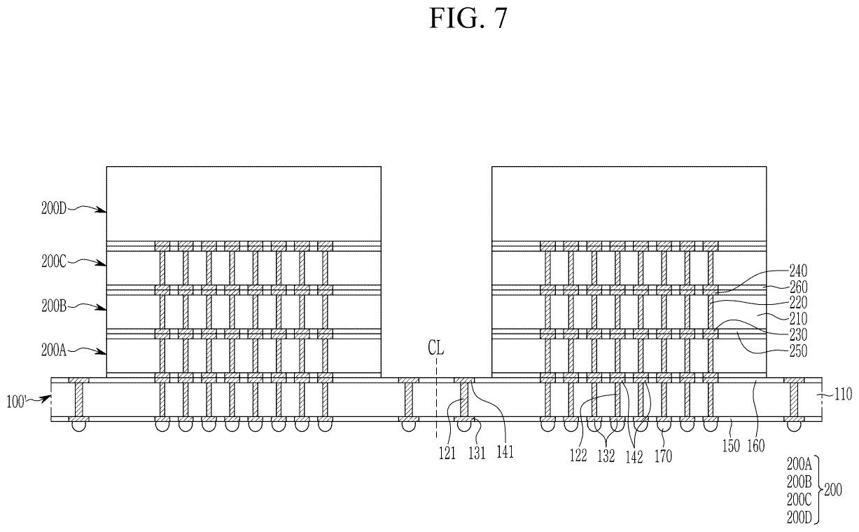

FIGS. 7 to 14 are diagrams of a manufacturing process for a semiconductor package according to an embodiment.

First, referring to FIG. 7, chip structure(s) 200 may be disposed on a wafer 100′.

The wafer 100′ may be structured to be cut along a cutting line CL and separated into individual first semiconductor chips 100. Accordingly, the wafer 100′ may include the first semiconductor substrate 110, the first and second through vias 121 and 122, the first to fourth pads 131, 141, 132, and 142, and the first and second passivation films 150 and 160, the elements included in the first semiconductor chip 100 as described above.

The chip structure 200 may include a plurality of stacked second semiconductor chips 200A, 200B, 200C, and 200D. Each of the second semiconductor chips 200A, 200B, 200C, and 200D may include the second semiconductor substrate 210, the third through via 220, the fifth and sixth pads 230 and 240, and the third and fourth passivation films 250 and 260.

The chip structure 200 may be formed on the wafer 100′ by sequentially arranging the second semiconductor chips 200A, 200B, 200C, and 200D on the wafer 100′, or may be formed separately and arranged on the wafer 100′ in the state of the chip structure 200.

The wafer 100′ and the chip structure 200 may be hybrid-bonded. The second semiconductor chips 200A, 200B, 200C, and 200D of the chip structure 200 may be hybrid-bonded.

FIG. 7 shows only a part of the wafer 100′ where two adjacent chip structures 200 are arranged, and a greater number of chip structures 200 than those shown in the drawing may be arranged on the wafer 100′.

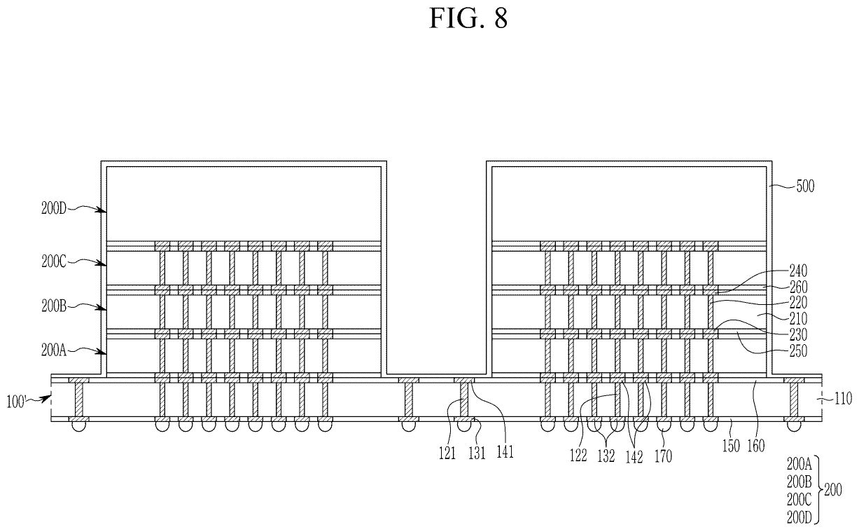

Next, referring to FIG. 8, the insulating layer 500 covering the wafer 100′ and the chip structure 200 may be formed. The insulating layer 500 may be performed by a deposition process. For example, the insulating layer 500 may be formed by chemical vapor deposition (CVD), physical vapor deposition (PVD), atomic layer deposition (ALD), or a combination of two or more of the above methods.

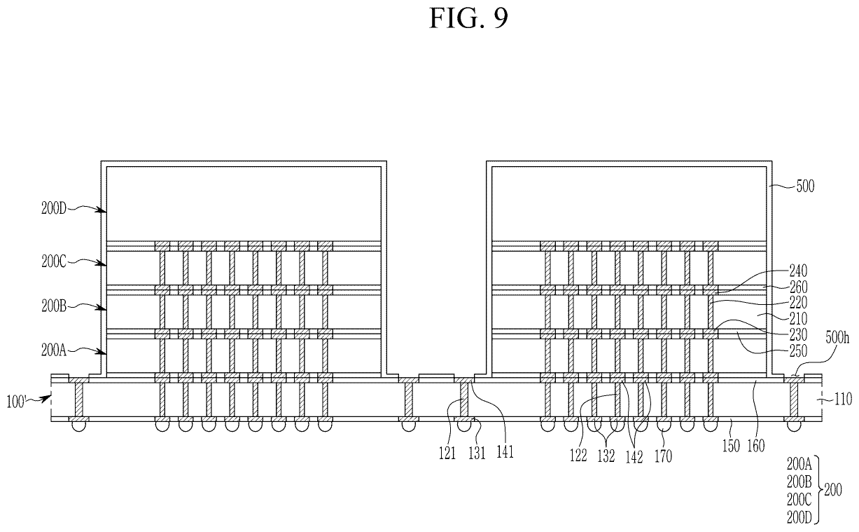

Next, referring to FIG. 9, the opening 500h including a region overlapping the first through via 121 may be formed on the insulating layer 500. The opening 500h may be formed by laser processing, dry etching, wet etching, etc.

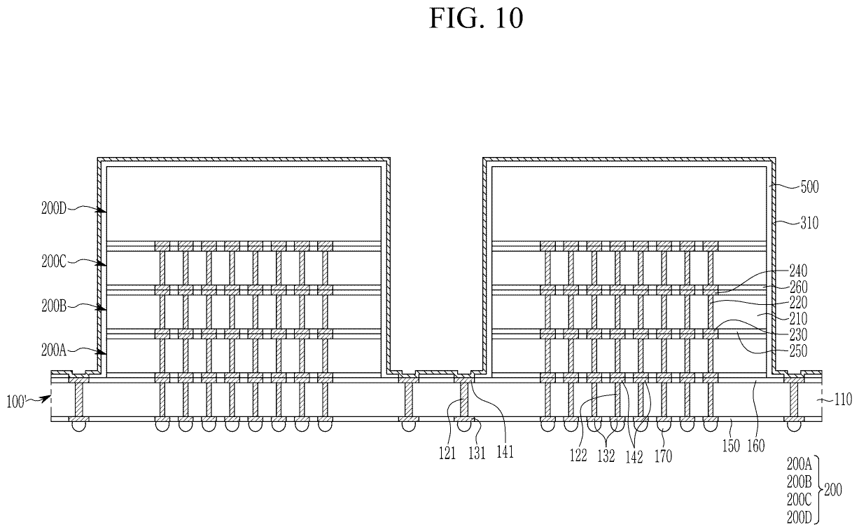

Next, referring to FIG. 10, the first shielding film 310 may be formed to cover the insulating layer 500 and may be electrically connected to the first through via 121.

The first shielding film 310 may fill at least a part of the opening 500h of the insulating layer 500. For example, the first shielding film 310 may be formed to extend along the wall surface and the bottom surface of the opening 500h. Accordingly, the first shielding film 310 may be connected to the first through via 121 through the second pad 141 exposed through the opening 500h of the insulating layer 500.

The first shielding film 310 may be formed by a deposition process. For example, the first shielding film 310 may be formed by chemical vapor deposition (CVD), physical vapor deposition (PVD), atomic layer deposition (ALD), or a combination of two or more of the above methods.

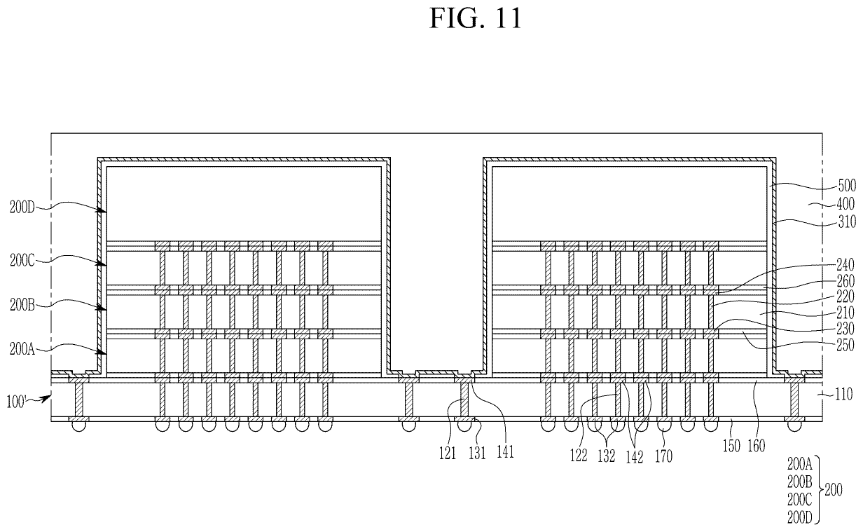

Next, referring to FIG. 11, the molding material 400 covering the first shielding film 310 may be formed. The molding material 400 may be formed through compression molding, transfer molding, etc.

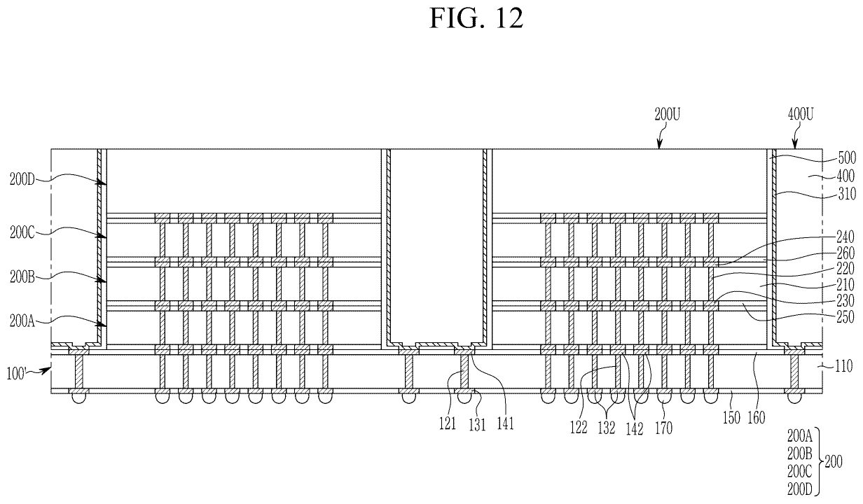

Next, referring to FIG. 12, the molding material 400, the first shielding film 310, and the insulating layer 500 may be ground to expose the chip structure 200. By processing an upper surface of the uppermost semiconductor chip 200D during the grinding to adjust the thickness of the chip structure 200, the semiconductor package 10A that meets product specifications may be provided.

Meanwhile, depending on the embodiment, only the molding material 400 may be ground in the grinding process, and the first shielding film 310 and the insulating layer 500 may remain on the chip structure 200. In this embodiment, the formation of the second shielding film 320 may be unnecessary, and this embodiment should also be considered to be included in the disclosure.

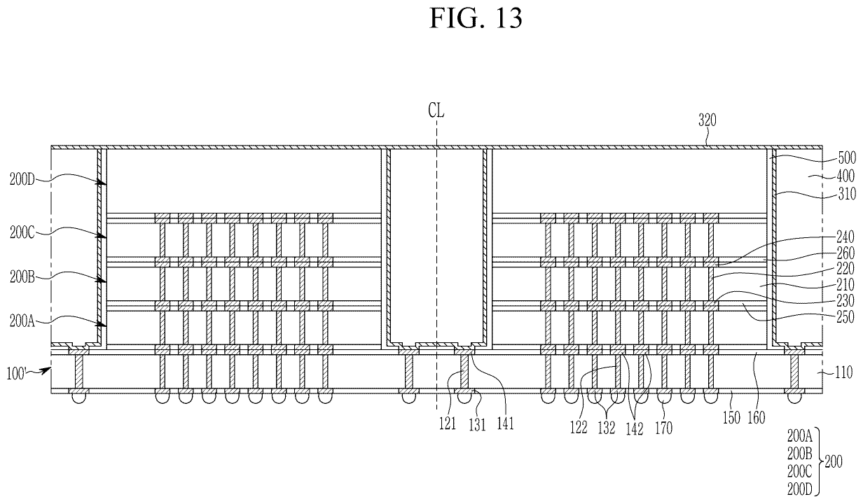

Next, referring to FIG. 13, the second shielding film 320 may be formed on the chip structure 200 and the molding material 400 to form a wafer-level semiconductor package. The second shielding film 320 may be formed by a deposition process, like the first shielding film 310.

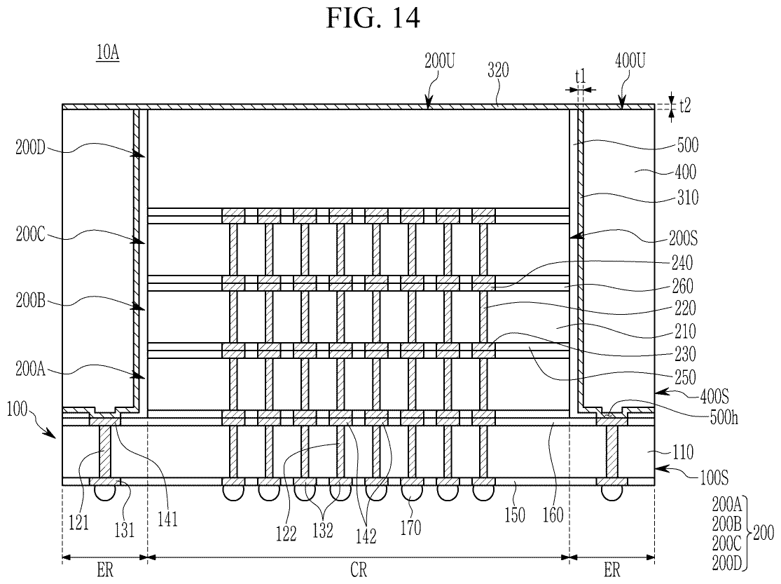

Finally, referring to FIG. 14, individual semiconductor packages 10A may be manufactured by singulating a wafer-level semiconductor package. Singulation may be performed by cutting a wafer-level semiconductor package along the cutting line CL (refer to FIG. 13) between the chip structures 200. The cutting may be performed by at least one of laser processing and blade processing.

While the example embodiments of the disclosure have been described in detail, it is to be understood that the disclosure is not limited to the disclosed embodiments, but on the contrary, is intended to cover various modifications and equivalent arrangements included within the spirit and scope of the appended claims and their equivalents.

In addition, the embodiments of the disclosure are not independent of each other and may be implemented in combination with each other unless they are specifically contradictory. Accordingly, embodiments in which the embodiments of the disclosure are combined should also be considered to be included in the disclosure.

What is claimed is:

1. A semiconductor package, comprising:
a first semiconductor chip including a semiconductor substrate and a through via penetrating the semiconductor substrate;
a chip structure on the first semiconductor chip and including at least one second semiconductor chip;
a first shielding film covering a side surface of the chip structure, extending over the first semiconductor chip, and electrically connected to the through via;
a molding material covering the first shielding film, on the first semiconductor chip; and
a second shielding film extending over the chip structure and the molding material, and connected to the first shielding film.

2. The semiconductor package of claim 1, further comprising:
an insulating layer extending between the chip structure and the first shielding film and between the first semiconductor chip and the first shielding film.

3. The semiconductor package of claim 2, wherein the insulating layer has an opening including a region overlapping the through via.

4. The semiconductor package of claim 2, wherein the insulating layer comprises at least one of silicon oxide and silicon nitride.

5. The semiconductor package of claim 1, wherein an upper surface of the chip structure and an upper surface of the molding material are substantially coplanar.

6. The semiconductor package of claim 1, wherein the first shielding film extends to a level of an upper surface of the chip structure.

7. The semiconductor package of claim 1, wherein the first shielding film is exposed to a side surface of the molding material on the first semiconductor chip.

8. The semiconductor package of claim 1, wherein the through via comprises a ground via.

9. The semiconductor package of claim 1, wherein a thickness of each of the first shielding film and the second shielding film is 0.1 μm or greater and 20 μm or less.

10. The semiconductor package of claim 1, wherein the through via is misaligned with the chip structure in a vertical direction.

11. The semiconductor package of claim 1, wherein a side surface of the first semiconductor chip and a side surface of the molding material are substantially coplanar.

12. A semiconductor package, comprising:
a first semiconductor chip having a central region and an edge region surrounding the central region, the first semiconductor chip including a first semiconductor substrate extending in the central region and the edge region, a first through via penetrating the first semiconductor substrate at the edge region, a first pad and a second pad respectively on opposite surfaces of the first semiconductor chip and electrically connected to the first through via, a second through via penetrating the first semiconductor substrate in the central region, and a third pad and a fourth pad respectively on the opposite surfaces of the first semiconductor chip and connected to the second through via;
a chip structure on the central region of the first semiconductor chip and including a plurality of stacked second semiconductor chips, each second semiconductor chip including a second semiconductor substrate, a third through via penetrating the second semiconductor substrate, and a fifth pad and a sixth pad respectively on opposite surfaces of each second semiconductor chip and electrically connected to the third through via;
a first shielding film covering a side surface of the chip structure, extending over the first semiconductor chip, and electrically connected to the first through via;
an insulating layer extending between the chip structure and the first shielding film and between the first semiconductor chip and the first shielding film;
a molding material covering the first shielding film on the first semiconductor chip; and
a second shielding film extending over the chip structure and the molding material and connected to the first shielding film,
wherein the fifth pad of each of the plurality of stacked second semiconductor chips is in contact with the sixth pad of another second semiconductor chip among the plurality of stacked second semiconductor chips or the fourth pad of the first semiconductor chip.

13. The semiconductor package of claim 12, wherein a diameter of the first through via is larger than a diameter of the second through via.

14. The semiconductor package of claim 12, wherein diameters of the first pad and the second pad are larger than diameters of the third pad and the fourth pad.

15. The semiconductor package of claim 12, wherein the first semiconductor chip further comprises a first passivation film in which the second pad and the fourth pad are embedded,
wherein each second semiconductor chip further comprises a second passivation film in which the fifth pad is embedded and a third passivation film in which the sixth pad is embedded, and
wherein the second passivation film of each of the plurality of stacked second semiconductor chips is in contact with the third passivation film of another second semiconductor chip among the plurality of stacked second semiconductor chips or the first passivation film of the first semiconductor chip.

16. The semiconductor package of claim 12, wherein the first semiconductor chip comprises a logic chip,
wherein each second semiconductor chip comprises a memory chip.

17. A manufacturing method for a semiconductor package, comprising:
placing a chip structure including a plurality of semiconductor chips stacked on a wafer, the wafer including a semiconductor substrate and a first through via penetrating the semiconductor substrate;
forming an insulating layer covering the wafer and the chip structure;
forming a first shielding film covering the insulating layer and electrically connected to the first through via;
forming a molding material covering the first shielding film;
grinding the molding material, the first shielding film, and the insulating layer to expose the chip structure;
forming a second shielding film on the chip structure and the molding material to form a wafer-level semiconductor package; and
singulating the wafer-level semiconductor package.

18. The manufacturing method for the semiconductor package of claim 17, wherein the forming the insulating layer is performed by a deposition process.

19. The manufacturing method for the semiconductor package of claim 17, wherein the forming the first shielding film and the forming the second shielding film are performed by a deposition process.

20. The manufacturing method for the semiconductor package of claim 17, further comprising:
forming an opening including a region overlapping the first through via in the insulating layer,
wherein in forming the first shielding film, the first shielding film fills the opening.
